(19) United States
(12) Patent Application Publication
(10) Pub. No.: US 2024/0379406 A1
(43) Pub. Date: Nov. 14, 2024

(54) SEMICONDUCTOR MEMORY DEVICE

(71) Applicant: Samsung Electronics Co., Ltd., Suwon-si (KR)

(72) Inventors: Hee Sung LEE, Suwon-si (KR); Tae Sung KANG, Suwon-si (KR); Se Min YANG, Suwon-si (KR); Kyo-Suk CHAE, Suwon-si (KR); Seung Ho HONG, Suwon-si (KR); Beom Yong HWANG, Suwon-si (KR)

(21) Appl. No.: 18/394,940

(22) Filed: Dec. 22, 2023

(30) Foreign Application Priority Data
May 8, 2023 (KR) 10-2023-0059160

(51) Int. Cl. H01L 21/762; H01L 29/423; H10B 12/00

(52) U.S. Cl. CPC H01L 21/76224; H01L 29/42364; H10B 12/482; H10B 12/488; H10B 12/50

(57) ABSTRACT

A semiconductor device is disclosed. The semiconductor memory device comprises a substrate including an active region, an element isolation film disposed in the substrate and that defines the active region, a recess which is disposed in the active region and extends in a first direction, and a gate structure extending in a second direction, on the active region, wherein the gate structure includes a gate insulating film, a gate stack pattern, and a gate capping pattern which are sequentially stacked, wherein the gate insulating film extends along an upper face of the active region, and a part of the gate insulating film fills the recess, and wherein a height from a lower face of the substrate to a bottom face of the element isolation film is less than a height from the lower face of the substrate to a bottom face of the recess.

### CROSS-REFERENCE TO RELATED APPLICATION

This application claims priority under 35 U.S.C. 119 to Korean Patent Application No. 10-2023-0059160 filed on May 8, 2023, in the Korean Intellectual Property Office, the contents of which in its entirety are herein incorporated by reference.

### BACKGROUND

### 1. Field of the Disclosure

The present disclosure relates to a semiconductor memory device.

### 2. Description of the Related Art

A semiconductor memory device includes numerous transistors. The transistors integrated in the semiconductor memory device are formed in various structures depending on required performances such as an operating voltage and/or a driving current. For example, there is a complementary mode (CMOS) element structure in which a NMOS element and a PMOS element have metal gate electrodes of different conductivity types from each other. In such structures, even when the thickness of a gate insulating film in each element are the same, the intensity of electric field (E-field) increases at an insulating film (corner Gox) of a corner of an active pattern, and a threshold voltage of the transistor may vary depending on the ratio of the corners.

### SUMMARY

Aspects of the present disclosure provide a semiconductor memory device having improved element performance and reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising, a substrate including an active region, an element isolation film disposed in the substrate and that defines the active region, a recess which is disposed in the active region and extends in a first direction, and a gate structure extending in a second direction, on the active region, wherein the gate structure includes a gate insulating film, a gate stack pattern, and a gate capping pattern which are sequentially stacked, wherein the gate insulating film extends along an upper face of the active region, and a part of the gate insulating film fills the recess, and wherein a height from a lower face of the substrate to a bottom face of the element isolation film is less than a height from the lower face of the substrate to a bottom face of the recess.

According to another aspect of the present disclosure, there is provided a semiconductor memory device comprising, a substrate that includes an active region including a plurality of sub-regions, an element isolation film which is disposed in the substrate and defines the active region, and a plurality of sub-element isolation films which are disposed in the substrate, extend in a first direction, are spaced apart from each other in a second direction, and defines the plurality of sub-regions, wherein a height of each of the plurality of sub-element isolation films in a third direction is less than a height of the element isolation film in the third direction, and wherein widths of the plurality of sub-element isolation films in the second direction are less than widths of the plurality of sub-regions in the second direction.

According to another aspect of the present disclosure, there is provided a semiconductor memory device comprising, a substrate including a cell array region and a peripheral region, a plurality of memory cells which are disposed in the cell array region, and each include a word line, a bit line, and a capacitor, a peripheral element isolation film which is disposed in the peripheral region of the substrate, and defines a peripheral active region, at least one or more recesses disposed in the peripheral active region, a peripheral sub-element isolation film disposed in the recess, and a plurality of transistors which are disposed on the substrate of the peripheral region, and control operations of the plurality of memory cells, wherein a height from an upper face of the substrate to a bottom face of the peripheral element isolation film is greater than a height from an upper face of the substrate to a bottom face of the peripheral sub-element isolation film.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a semiconductor memory device according to some embodiments.

FIG. 2 is across-sectional view taken along line A-A of FIG. 1 according to some embodiments.

FIG. 3 is an enlarged view of a region P of FIG. 2 according to some embodiments.

FIG. 4 is a cross-sectional view taken along line B-B of FIG. 1 according to some embodiments.

FIG. 5 is a cross-sectional view taken along line C-C of FIG. 1 according to some embodiments.

FIGS. 6 to 8 are cross-sectional diagrams of a semiconductor memory device according to some embodiments.

FIGS. 9 and 10 are cross-sectional diagrams of a semiconductor memory device according to some embodiments.

FIGS. 11 and 12 are cross-sectional diagrams of a semiconductor memory device according to some embodiments.

FIGS. 13 and 14 are cross-sectional diagrams of a semiconductor memory device according to some embodiments.

FIG. 15 is a cross-sectional diagram of a semiconductor memory device according to some embodiments.

FIG. 16 is a cross-sectional diagram of a semiconductor memory device according to some embodiments.

FIG. 17 is a plan view of a semiconductor memory device according to some embodiments.

FIG. 18 is a cross-sectional view taken along lines D-D, E-E and F-F of FIG. 17.

FIGS. 19 to 25 are cross-sectional views sequentially showing an example of a processes of fabricating a semiconductor memory device having the cross-section of FIG. 2.

### DETAILED DESCRIPTION OF THE EMBODIMENTS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Hereinafter, embodiments according to the technical idea of the present disclosure will be explained with reference to the accompanying drawings.

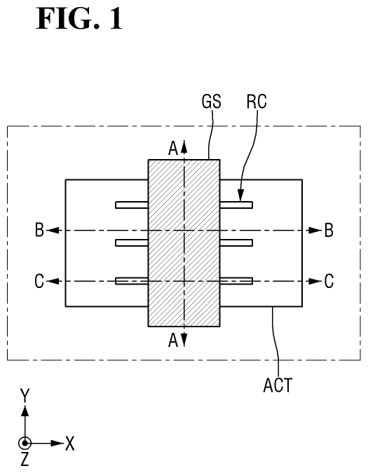

FIGS. 1 to 5 illustrate a semiconductor memory device according to some embodiments. Although the figures show a dynamic random access memory (DRAM), embodiments of the technical idea of the present disclosure are not limited thereto.

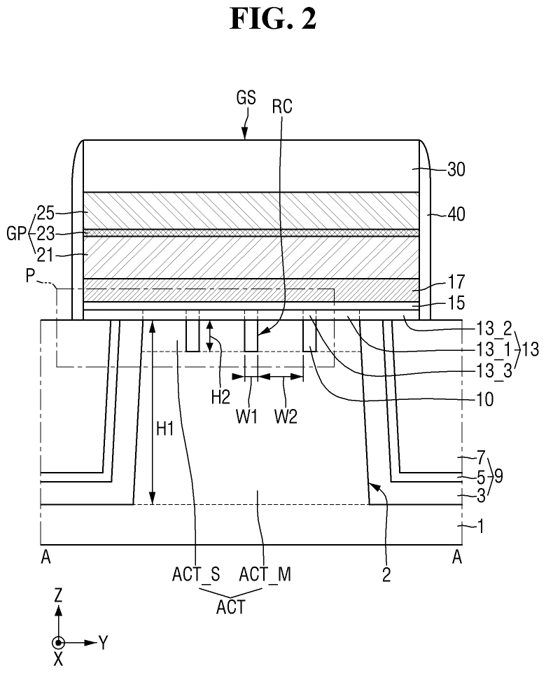

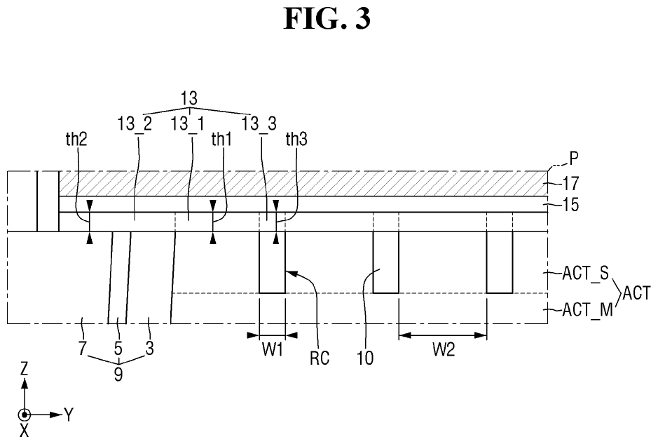

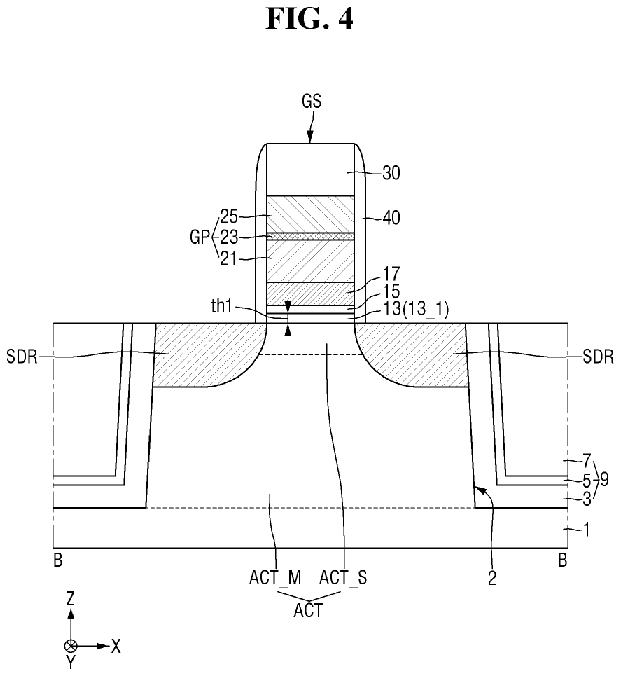

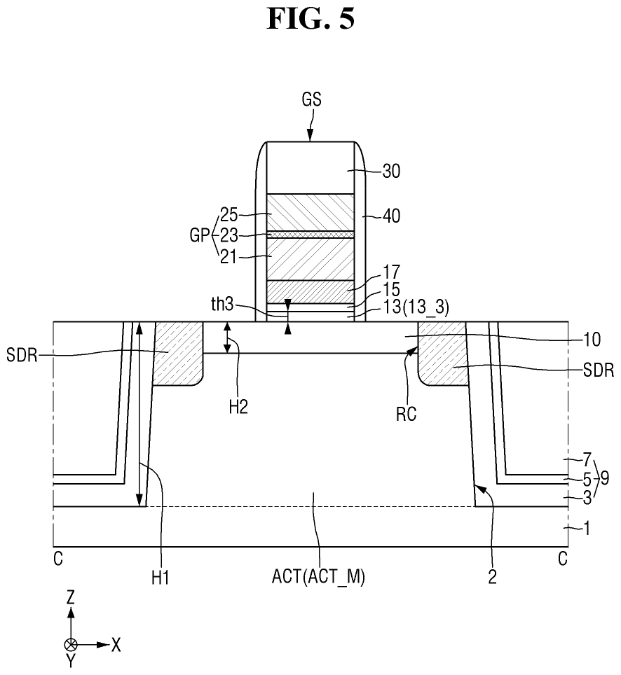

FIG. 1 is a plan view of a semiconductor memory device according to some embodiments. FIG. 2 is a cross-sectional view taken along line A-A of FIG. 1 according to some embodiments. FIG. 3 is an enlarged view of a region P of FIG. 2 according to some embodiments. FIG. 4 is a cross-sectional view taken along line B-B of FIG. 1 according to some embodiments. FIG. 5 is an exemplary cross-sectional view taken along line C-C of FIG. 1 according to some embodiments.

Referring to FIGS. 1 to 5, the semiconductor memory device according to some embodiments may include a substrate 1, an element isolation film 9, a sub-element isolation film 10, and a gate structure GS.

First, the substrate 1 is provided. The substrate 1 may be, for example, a silicon single crystal substrate or an SOI (Silicon on Insulator) substrate. In some embodiments, the substrate 1 may be formed of and/or include, but is not limited to, silicon germanium, SGOI (silicon germanium on insulator), indium antimonide, lead telluride, indium arsenide, indium phosphide, gallium arsenide or gallium antimonide.

A trench 2 may be disposed in the substrate 1 (e.g., the substrate may have a trench formed therein). An element isolation film 9 may be disposed inside the trench 2. The element isolation film 9 may define an active region ACT (e.g., a portion of the substrate 1 laterally adjacent the element isolation film may form an active region ACT). The active region ACT may include a main active region ACT_M and at least one or more sub-regions ACT_S. The at least one or more sub-regions ACT_S may be defined by a sub-element isolation film 10, which will be described below. The main active region ACT_M may be a region of the active region ACT excluding the sub-region ACT_S.

In some embodiments, the active region ACT may extend in an x-direction X (e.g., a first horizontal direction relative to the substrate). For example, in FIG. 1, the active region ACT may include a long side extending in the x-direction X, and a short side extending in a y-direction Y (e.g., a second horizontal direction relative to the substrate). A length of the long side may be greater than a length of the short side.

Herein, the x-direction X and the y-direction Y may intersect each other. The x-direction X and the y-direction Y may be substantially perpendicular to each other. The x-direction X and the y-direction Y may be parallel to an upper face of the substrate 1. A z-direction Z (e.g., a vertical direction) may intersect the x-direction X and the y-direction Y. The z-direction Z may be substantially perpendicular to the x-direction X and the y-direction Y. The z-direction Z may be a direction perpendicular to the upper face of the substrate 1.

The element isolation film 9 may include a first liner film 3 that conformally covers the inner side walls and a bottom face of the trench 2, a buried insulating film 7 that fills the trench 2, and a second liner film 5 interposed between the first liner film 3 and the buried insulating film 7. The second liner film 5 may be disposed along the profile of the first liner film 3. The buried insulating film 7 may be disposed on the second liner film 5. The buried insulating film 7 may fill a remaining portion of the trench 2 after the first liner film 3 and the second liner film 5 are disposed therein.

The first liner film 3 may be formed of and/or include an insulating material. For example, the first liner film 3 may be formed of and/or include silicon oxide. The second liner film 5 may be formed of and/or include an insulating material. The second liner film 5 may be formed of a material different from that of the first liner film 3. For example, the second liner film 5 may be formed of and/or include silicon nitride. The buried insulating film 7 may be formed of and/or include an insulating material. The buried insulating film 7 may be formed of a material different from that of the second liner film 5. For example, the buried insulating film 7 may be formed of and/or include silicon oxide.

A recess RC may be formed in the substrate 1. The recess RC may extend in the x-direction X. As shown in FIG. 1, the recess RC may include a long side extending in the x-direction X and a short side extending in the y-direction Y. A length of the long side may be greater than a length of the short side.

In some embodiments, a depth of the recess RC in the z-direction Z is less than a depth of the trench 2 in the z-direction Z. For example, a second height H2 from the upper face of the recess RC to the bottom face of the recess RC is less than a first height H1 from the upper face of the trench 2 to the bottom face of the trench 2. Moreover, the upper face of the recess RC and the upper face of the trench 2 may be disposed on the same plane. A level of the bottom face of the trench 2 may be lower than a level of the bottom face of the recess RC on the basis of the lower face of the substrate 1. A second height H2 from the upper face of the substrate 1 to the bottom face of the recess RC may be less than the first height H1 from the upper face of the substrate 1 to the bottom face of the trench 2. The height from the lower face of the substrate 1 to the bottom face of the element isolation film 9 may be less than the height from the lower face of the substrate 1 to the bottom face of the recess RC.

In some embodiments, a height in the z-direction Z from the bottom face of the element isolation film 9 to the bottom face of the recess RC may be greater than the second height H2 from the bottom face of the recess RC to the upper face of the recess RC.

A sub-element isolation film 10 may be disposed inside the recess RC. The sub-element isolation film 10 may define a plurality of the sub-regions ACT_S. The sub-element isolation film 10 may extend in the x-direction X. The sub-element isolation films 10 may be spaced apart from each other in the y-direction Y. The sub-element isolation film 10 may be formed of and/or include an insulating material. For example, the sub-element isolation film 10 may be formed of and/or include silicon oxide, but embodiments of the technical idea of the present disclosure is not limited thereto.

In some embodiments, the depth of the sub-element isolation film 10 in the z-direction Z is less than the depth of the element isolation film 9 in the z-direction Z. For example, the second height H2 from the upper face of the sub-element isolation film 10 to the bottom face of the sub-element isolation film 10 is less than the first height H1 from the upper face of the element isolation film 9 to the bottom face of the element isolation film 9.

Also, the upper face of the sub-element isolation film 10 and the upper face of the element isolation film 9 may be disposed on the same plane. The level of the bottom face of the element isolation film 9 may be lower than the level of the bottom face of the sub-element isolation film 10 relative to the lower face of the substrate 1. The height from the lower face of the substrate 1 to the bottom face of element isolation film 9 may be less than the height from the lower face of the substrate 1 to the bottom face of the sub-element isolation film 10. The second height H2 from the upper face of the substrate 1 to the bottom face of the sub-element isolation film 10 may be less than the first height H1 from the upper face of the substrate 1 to the bottom face of the element isolation film 9.

The height in the z-direction Z from the bottom face of the element isolation film 9 to the bottom face of the sub-element isolation film 10 may be greater than the second height H2 from the bottom face of the sub-element isolation film 10 to the upper face of the sub-element isolation film 10.

In some embodiments, a first width W1 in the y-direction Y of the upper face of the sub-element isolation film 10 is less than the second width W2 in the y-direction Y of the upper face of the sub-region ACT_S between the sub-element isolation films 10. The widths in the y-direction Y of the upper faces of the plurality of the sub-element isolation films 10 are greater than the widths in the y-direction Y of the upper faces of the plurality of the sub-regions ACT_S.

In some embodiments, there may be at least one sub-element isolation film 10. Although FIG. 2 shows an example in which there are three sub-element isolation films 10, embodiments implementing the technical idea of the present disclosure are not limited thereto. The number of the sub-element isolation films 10 may be changed as desired. With at least one or more sub-element isolation films 10 disposed in the active region ACT, a threshold voltage of the transistor may be lowered due to the at least one or more sub-element isolation films 10 disposed in the active region ACT. Accordingly, a semiconductor memory device having improved reliability can be provided though the implementation of the sub-element isolation films as described in this disclosure.

For example, when the sub-element isolation film 10 is disposed as described, a ratio of a portion of a gate insulating film disposed at a corner portion of the active region ACT to a portion of the gate insulating film disposed on the upper face of the active region ACT increases. As the ratio of the gate insulating film 13 disposed at the corner portion relative to the upper face of the active region ACT increases, the threshold voltage of the transistor may be lowered.

In some embodiments, a source/drain region SDR may be disposed in the substrate 1.

The source/drain region SDR may be disposed on a first side and a second side opposing the first side of the gate structure GS. The source/drain region SDR may be disposed on a first side and a second side opposing the first side of the sub-region ACT_S. Impurities may be doped in the source/drain region SDR. For example, N-type impurities may be doped in the source/drain region SDR of the NMOS region. P-type impurities may be doped in the source/drain region SDR of the PMOS region. As an example, N-type impurities may be doped the source/drain region SDR of FIGS. 4 and 5, but embodiments of the technical idea are not limited thereto.

A gate structure GS may be disposed on the substrate 1. The gate structure GS may extend in the y-direction Y. As shown in FIG. 1, the gate structure GS may include a long side extending in the y-direction Y and a short side extending in the x-direction X. The length of the long side is longer than the length of the short side. In some embodiments, the width of the gate structure GS in the x-direction X may be less than the width of the recess RC in the x-direction X. The width of the gate structure GS in the y-direction Y may be greater than the width of the active region ACT in the y-direction Y. The gate structure GS may include a portion that overlaps the element isolation film 9 in the z-direction Z. However, embodiments of the technical idea of the present disclosure are not limited thereto.

The gate structure GS may include a gate insulating film 13, a high dielectric constant film 15, a work function pattern 17, a gate stack pattern GP, a gate capping film 30, and a gate spacer 40.

The gate insulating film 13, the high dielectric constant film 15, the work function pattern 17, the gate stack pattern GP, and the gate capping film 30 may be sequentially stacked in the z-direction Z. The gate spacer 40 may be disposed along the side walls of the gate insulating film 13, the high dielectric constant film 15, the work function pattern 17, the gate stack pattern GP, and the gate capping film 30.

The gate insulating film 13 may extend along the upper face of the element isolation film 9, the upper face of the active region ACT, and the upper face of the sub-element isolation film 10. The gate insulating film 13 may include a first portion 13_1 that overlaps the upper face of the active region ACT in the z-direction Z, a second portion 13_2 that overlaps the upper face of the element isolation film 9 in the z-direction Z, and a third portion 13_3 that overlaps the upper face of the sub-element isolation film 10 in the z-direction Z.

The first portion 13_1 may extend along the upper face of the active region ACT. The first portion 13_1 may be in contact with the active region ACT. The first portion 13_1 may extend along the upper face of the sub-region ACT_S. The first portion 13_1 may be in contact with the upper face of the sub-region ACT_S. The second portion 13_2 may extend along a part of the upper face of the element isolation film 9. The second portion 13_2 may be in contact with a part of the buried insulating film 7, an uppermost part of the second liner film 5, and an uppermost part of the first liner film 3. The third portion 13_3 may be in contact with the third portion 13_3. The third portion 13_3 may extend along the upper face of the sub-element isolation film 10. The third portion 13_3 may be in contact with the sub-element isolation film 10.

As shown in FIG. 3, the first portion 13_1 may have a first thickness th1 in the z-direction Z. The second portion 13_2 may have a second thickness th2 in the z-direction Z. The third portion 13_3 may have a third thickness th3 in the z-direction Z. The first thickness th1 and the second thickness th2 may be the same as each other. The third thickness th3 may be the same as the first thickness th1 and the second thickness th2. That is, the thickness of the gate insulating film 13 may be constant.

As shown in FIG. 4, the first portion 13_1 may be disposed between the source/drain regions SDR. The first portion 13_1 may be disposed on the sub-region ACT_S. As shown in FIG. 5, the third portion 13_3 may be disposed on the sub-element isolation film 10. The width of the sub-element isolation film 10 in the x-direction X is greater than the width of the third portion 13_3 in the x-direction X.

The gate insulating film 13 may be formed of and/or include, for example, silicon oxide, silicon oxynitride or a combination thereof.

The high dielectric constant film 15 may be disposed on the gate insulating film 13. The high dielectric constant film 15 may be formed of and/or include a material having a dielectric constant greater than that of silicon oxide. For example, the high dielectric constant film 15 may be formed of and/or include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The work function pattern 17 may be disposed on the high dielectric constant film 15. The work function pattern 17 of the NMOS region may include an N-type metal. The work function pattern 17 of the PMOS region may include a P-type metal. In FIGS. 2 to 5, the work function pattern 17 may include the N-type metal. For example, the work function pattern 17 may be formed of and/or include at least one of lanthanum (La), lanthanum oxide (LaO), magnesium (Mg), magnesium oxide (MgO), tantalum (Ta), tantalum nitride (TaN), and niobium (Nb).

The gate stack pattern GP may be disposed on the work function pattern 17. The gate stack pattern GP may include a lower electrode 21, a central electrode 23, and an upper electrode 25. The lower electrode 21, the central electrode 23, and the upper electrode 25 may be stacked sequentially. That is, the central electrode 23 may be disposed on the lower electrode 21. The upper electrode 25 may be disposed on the central electrode 23. The lower electrode 21 may abut on the work function pattern 17. The upper electrode 25 may abut on the gate capping film 30. The central electrode 23 may abut on the lower electrode 21 and the upper electrode 25.

The lower electrode 21 may be formed of and/or include impurity-doped polysilicon. The lower electrode 21 of the NMOS region may be doped with N-type impurities. The lower electrode 21 of the PMOS region may be doped with P-type impurities. As shown in FIGS. 2 to 5, the lower electrode 21 may be doped with N-type impurities, but embodiments are not limited thereto.

The central electrode 23 may be formed of and/or include TiSiN. The upper electrode 25 may be formed of and/or include tungsten (W). However, embodiments of the technical idea of the present disclosure are not limited thereto.

The gate capping film 30 may be disposed on the gate stack pattern GP. The gate capping film 30 may be disposed on the upper electrode 25. The gate capping film 30 may be formed of and/or include a nitride-based insulating material. For example, the gate capping film 30 may include, but is not limited to, silicon nitride.

The gate spacer 40 may be disposed on side walls of the gate insulating film 13, the high dielectric constant film 15, the work function pattern 17, the gate stack pattern GP, and the gate capping film 30. In FIG. 2, the gate spacer 40 may be disposed on the element isolation film 9. In FIG. 4, the gate spacer 40 may be disposed on the source/drain region SDR. In FIG. 5, the gate spacer 40 may be disposed on the sub-element isolation film 10. The gate spacer 40 may be formed of and/or include, for example, but is not limited to, one of a silicon oxide film, a silicon nitride film, a silicon oxynitride film (SiON), a silicon oxycarbonitride film (SiOCN), air, and combinations thereof.

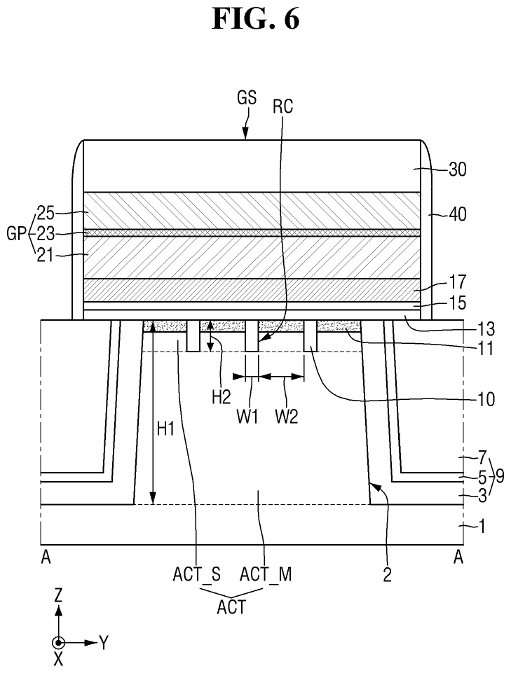

Semiconductor memory devices according to some other embodiments will be described below with reference to FIGS. 6 to 16. For convenience of explanation, description of r parts of contents previously explained using FIGS. 1 to 5 may be omitted or explained only briefly.

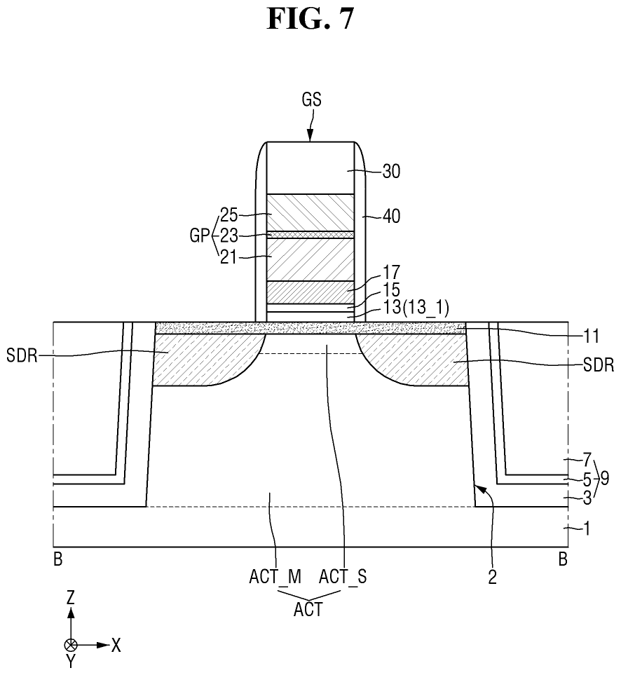

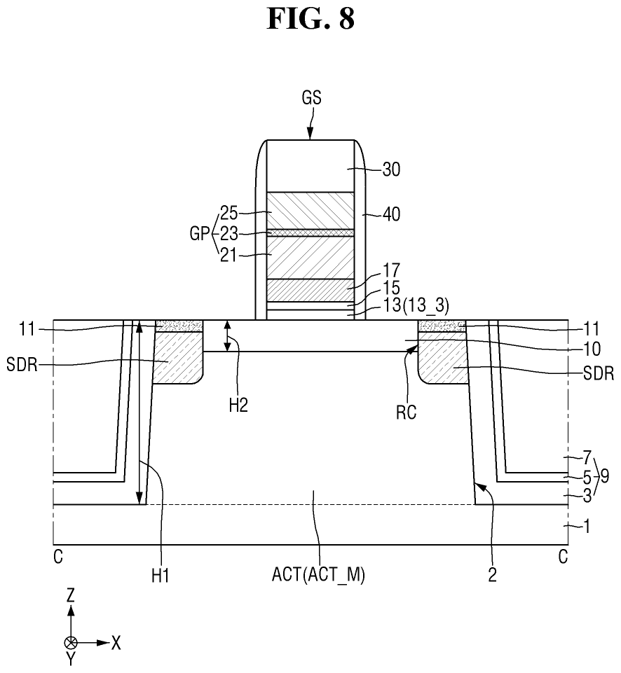

FIGS. 6 to 8 are cross-sectional diagrams of a semiconductor memory device according to some other embodiments. For reference, FIG. 6 is an exemplary cross-sectional view taken along line A-A of FIG. 1, FIG. 7 is an exemplary cross-sectional view taken along line B-B of FIG. 1, and FIG. 8 is an exemplary cross-sectional view taken along line C-C of FIG. 1.

Referring to FIGS. 6 to 8, the semiconductor memory device according to some other embodiments may include a PMOS region.

The semiconductor memory device according to some embodiments may further include a channel layer 11. The channel layer 11 may be disposed in the substrate 1 of the PMOS region. A lattice constant of the channel layer 11 may be greater than that of the substrate 1. For example, the channel layer 11 may be formed of and/or include silicon germanium. The channel layer 11 may improve the mobility of holes in the PMOS transistor. Also, the channel layer 11 may play a role of lowering the work function.

A source/drain region SDR may be disposed under the channel layer 11. P-type impurities may be doped in the source/drain region SDR. The source/drain region SDR may be disposed on a first side and on a second side opposing the first side of the sub-element isolation film 10. The source/drain region SDR may be disposed on a first side and on a second side opposing the first side of the sub-region ACT_S.

As shown in FIG. 6, the channel layer 11 may be disposed between the element isolation film 9 and the sub-element isolation film 10, and between the sub-element isolation films 10. The thickness of the channel layer 11 in the z-direction Z is less than the second height H2 of the sub-element isolation film 10 in the z-direction Z.

As shown in FIG. 7, a part of the channel layer 11 may be disposed on the sub-region ACT_S. Another part of the channel layer 11 may be disposed on the source/drain region SDR. P-type impurities may be doped in the source/drain region SDR disposed under the channel layer 11.

A gate insulating film 13 may be disposed on the channel layer 11. The thickness of the gate insulating film 13 may be constant. For example, the thickness of the gate insulating film 13 that overlaps the upper face of the element isolation film 9, the thickness of the gate insulating film 13 that overlaps the upper face of the channel layer 11, and the thickness of the gate insulating film 13 that overlaps the upper face of the sub-element isolation film 10 may all be the same.

The high dielectric constant film 15 may be disposed on the gate insulating film 13. The work function pattern 17 may be disposed on the high dielectric constant film 15. The work function pattern 17 may include a P-type metal. For example, the work function pattern 17 may be formed of and/or include aluminum (Al), aluminum oxide film (AlO), titanium nitride (TiN), tungsten nitride (WN), and/or ruthenium oxide (RuO).

A gate stack pattern GP and a gate capping film 30 may be disposed on the work function pattern 17. The gate spacer 40 may be disposed on side walls of the gate insulating film 13, the side walls of the high dielectric constant film 15, the side walls of the work function pattern 17, the side walls of the gate stack pattern GP, and the side walls of the gate capping film 30. The lower electrode 21 of the gate stack pattern GP may be doped with P-type impurities.

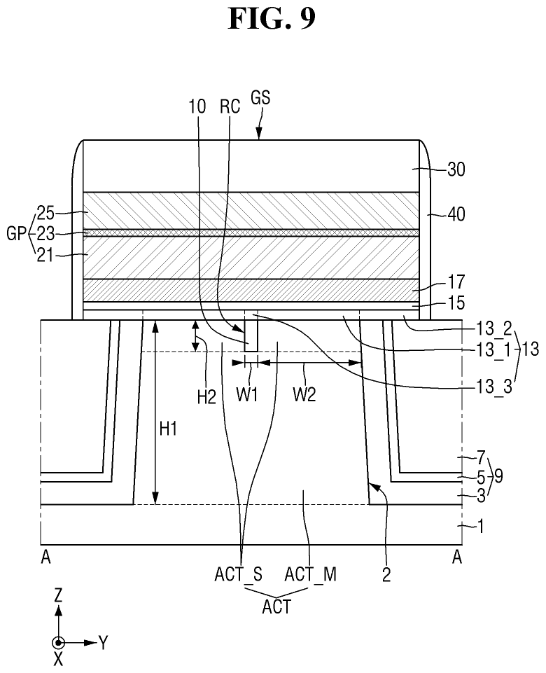

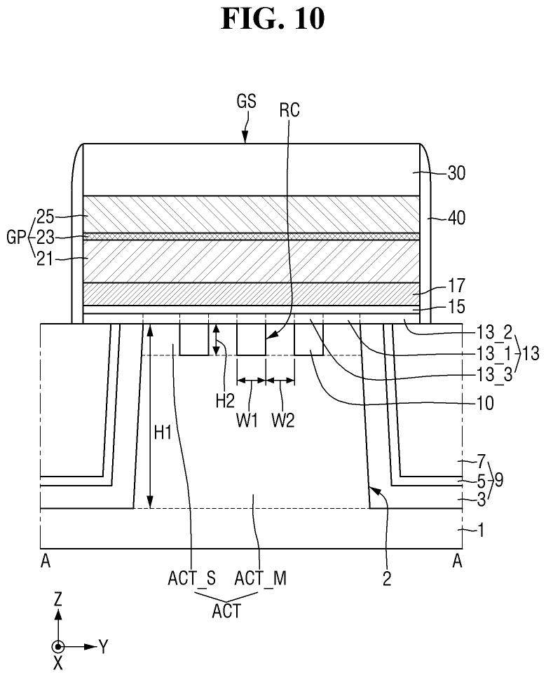

FIGS. 9 and 10 are cross sectional diagrams of a semiconductor memory device according to some other embodiments. For reference, FIGS. 9 and 10 are exemplary cross-sectional views taken along line A-A of FIG. 1, respectively.

As shown in FIG. 9, in some embodiments only one recess RC may be disposed in the substrate 1. One sub-element isolation film 10 may be disposed inside the recess RC. Accordingly, two sub-regions ACT_S may be formed in the substrate 1. The sub-region ACT_S may be disposed between the element isolation film 9 and the sub-element isolation film 10.

Referring to FIG. 10, a first width W1 in the y-direction Y of the upper face of the recess RC may be the same as a second width W2 in the y-direction Y of the upper face of the sub-region ACT_S between the recesses RC. The first width W1 in the y-direction Y of the upper face of the sub-element isolation film 10 may be the same as the second width W2 in the y-direction Y of the upper face of the sub-region ACT_S between the recesses RC. The width in the y-direction Y of the upper face of the active region ACT is greater than the widths in the y-direction Y of the upper faces of the recesses RC. The width in the y-direction Y of the upper face of the active region ACT is greater than the widths in the y-direction Y of the upper faces of the sub-element isolation films 10.

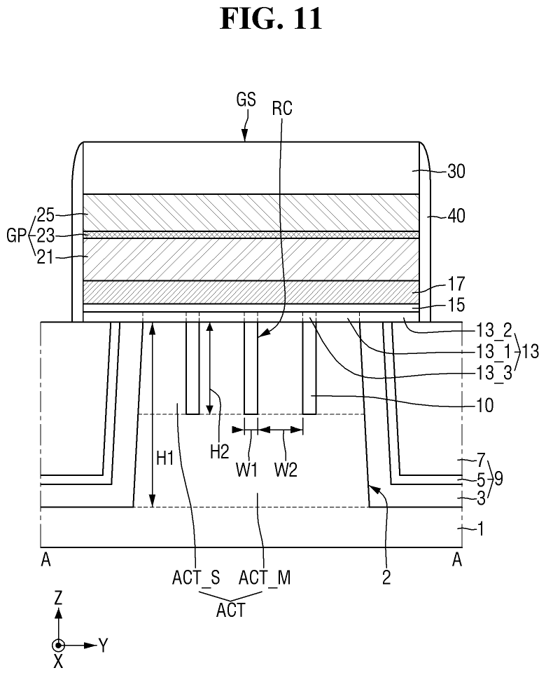

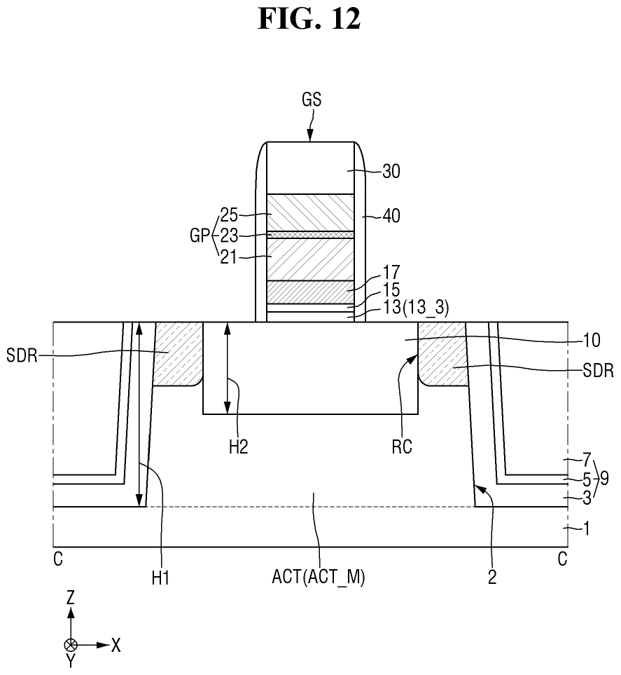

FIGS. 11 and 12 are cross sectional diagrams of a semiconductor memory device according to some other embodiments. FIG. 11 is an exemplary cross-sectional view taken along line A-A of FIG. 1, and FIG. 12 is an exemplary cross-sectional view taken along line C-C of FIG. 1.

As shown in FIGS. 11 and 12, a second height H2 from the upper face of the sub-element isolation film 10 to the bottom face of the sub-element isolation film 10 is less than the first height H1 from the upper face of the element isolation film 9 to the bottom face of the element isolation film 9. The height in the z-direction Z from the bottom face of the sub-element isolation film 10 to the bottom face of the element isolation film 9 may be the same as the second height H2 from the upper face of the sub-element isolation film 10 to the bottom face of the sub-element isolation film 10.

The source/drain region SDR may completely overlap the sub-element isolation film 10 in the x-direction X. That is, the height in the z-direction Z from the upper face of the substrate 1 to the lowest point of the bottom face of the source/drain region SDR may be less than the second height H2 from the upper face of the substrate 1 to the bottom face of the sub-element isolation film 10. At least a part of the sub-element isolation film 10 does not overlap the source/drain region SDR in the x-direction X.

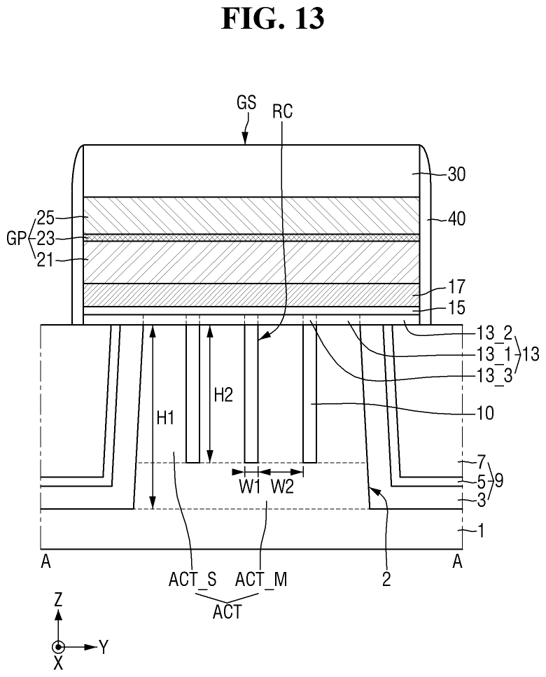

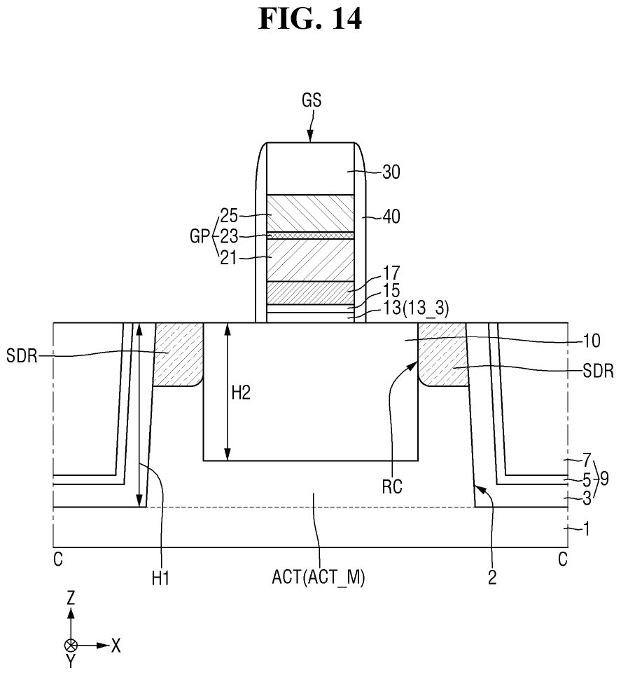

FIGS. 13 and 14 are cross sectional diagrams of a semiconductor memory device according to some other embodiments. For reference, FIG. 13 is an exemplary cross-sectional view taken along line A-A of FIG. 1, and FIG. 14 is an exemplary cross-sectional view taken along line C-C of FIG. 1.

Referring to FIGS. 13 and 14, the second height H2 from the upper face of the sub-element isolation film 10 to the bottom face of the sub-element isolation film 10 is less than the first height H1 from the upper face of the element isolation film 9 to the bottom face of the element isolation film 9.

The source/drain region SDR may completely overlap the sub-element isolation films 10 in the x-direction X. That is, the height in the z-direction Z from the upper face of the substrate 1 to the lowest point of the bottom face of the source/drain region SDR may be less than the first second height H2 from the upper face of the substrate 1 to the bottom face of the sub-element isolation film 10. At least a part of the sub-element isolation film 10 may not overlap the source/drain region SDR in the x-direction X.

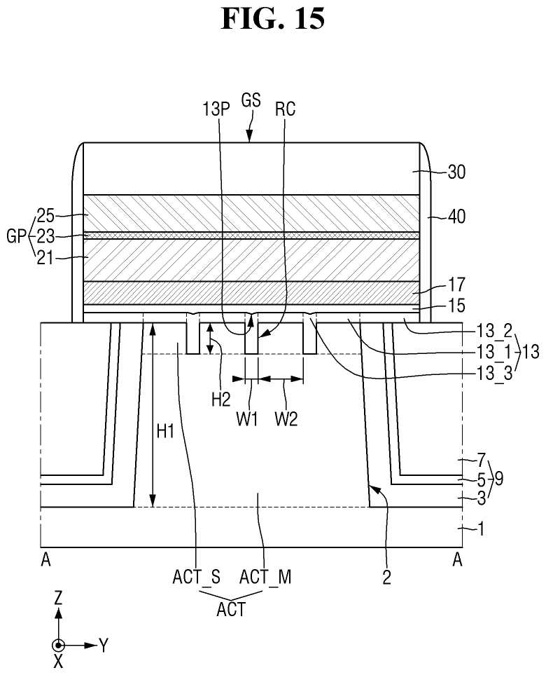

FIG. 15 is a cross sectional diagram of a semiconductor memory device according to some other embodiments.

Referring to FIG. 15, a part of the gate insulating film 13 may be disposed inside the recess RC. The gate insulating film 13 may be formed immediately after forming the recess RC. At this time, a part of the gate insulating film 13 may fill the recess RC. The sub-element isolation film may not be disposed inside the recess RC.

For example, the third portion 13_3 of the gate insulating film 13 may fill the recess RC. The first portion 13_1 of the gate insulating film 13 is disposed along the upper face of the cell active region ACTC. The second portion 13_2 of the gate insulating film 13 is disposed along the upper face of the element isolation film 9. The thickness of the first portion 13_1 of the gate insulating film 13 and the thickness of the second portion 13_2 of the gate insulating film 13 may be the same as each other.

In some embodiments, the gate insulating film 13 may further include a tip portion 13P. The tip portion 13P may be disposed on the upper face of the third portion 13_3 of the gate insulating film 13. A part of the upper face of the third portion 13_3 of the gate insulating film 13 may be convex toward the lower face of the substrate 1. A portion in which the upper face of the third portion 13_3 of the gate insulating film 13 is recessed toward the lower face of the substrate 1 may be the tip portion 13P. However, embodiments of the technical idea of the present disclosure are not limited thereto. It goes without saying that the upper face of the third portion 13_3 of the gate insulating film 13 may be flat.

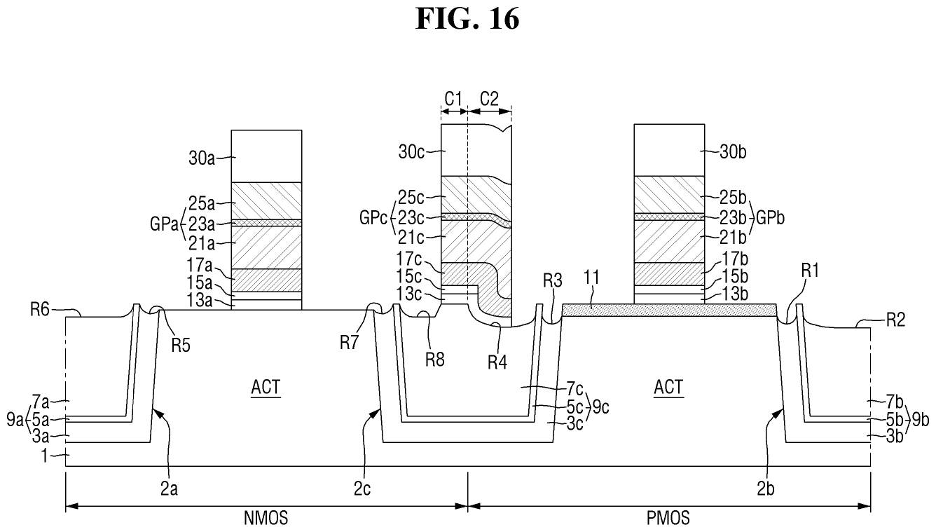

FIG. 16 is a cross sectional diagram for explaining a semiconductor memory device according to some other embodiments.

Referring to FIG. 16, a substrate 1 including the NMOS region and the PMOS region is provided.

A first trench 2a may be formed in the substrate 1 of the NMOS region. A second trench 2b may be formed in the substrate 1 of the PMOS region. A third trench 2c may be formed in the substrate 1 at a boundary between the NMOS region and the PMOS region. A first element isolation film 9a may be disposed inside the first trench 2a. A second element isolation film 9b may be disposed inside the second trench 2b. A dummy element isolation film 9c may be disposed inside the third trench 2c.

The first element isolation film 9a may include a first liner 3a that conformally covers the inner side wall and the bottom face of the first trench 2a, a first buried insulating film 7a that fills the first trench 2a, and a second liner 5a interposed between the first liner 3a and the first buried insulating film 7a.

The second element isolation film 9b may include a third liner 3b that conformally covers the inner side walls and the bottom face of the second trench 2b, a second buried insulating film 7b that fills the second trench 2b, and a fourth liner 5b interposed between the third liner 3b and the second buried insulating film 7b.

The dummy element isolation film 9c may include a fifth liner 3c that conformally covers the inner side wall and the bottom face of the third trench 2c, a third buried insulating film 7c that fills the third trench 2c, and a sixth liner 5c interposed between the fifth liner 3c and the third buried insulating film 7c.

The first liner 3a, the third liner 3b and the fifth liner 3c may include the same material. For example, the first liner 3a, the third liner 3b, and the fifth liner 3c may each be formed of and/or include silicon oxide. The second liner 5a, the fourth liner 5b and the sixth liner 5c may include the same material. For example, the second liner 5a, the fourth liner 5b, and the sixth liner 5c may each be formed of and/or include silicon nitride. The first buried insulating film 7a, the second buried insulating film 7b, and the third buried insulating film 7c may include the same material. For example, the first buried insulating film 7a, the second buried insulating film 7b, and the third buried insulating film 7c may each be formed of and/or include silicon oxide.

A first gate stack pattern GPa may be disposed on the substrate 1 of the NMOS region. Although not shown, a source/drain may be disposed in the substrate 1 on both sides of the first gate stack pattern GPa. For example, N-type impurities may be doped in the source/drain of the NMOS region.

The channel layer 11 may be disposed on the substrate 1 of the PMOS region. The lattice constant of the channel layer 11 may be greater than that of the substrate 1. For example, the channel layer 11 may be formed of and/or include silicon germanium. The channel layer 11 may be formed of and/or include silicon germanium. The channel layer 11 may improve mobility of the holes in the PMOS transistor. Also, the channel layer 11 may play a role of lowering the work function. A second gate stack pattern GPb may be disposed on the channel layer 11. Although not shown, a source/drain may be disposed in the channel layer 11 and the substrate 1 on both sides of the second gate stack pattern GPb. The source/drain of the PMOS region may be doped with P-type impurities.

A dummy gate stack pattern GPc may be disposed at the boundary between the NMOS region and the PMOS region. The dummy gate stack pattern GPc does not have a substantial function in the semiconductor memory device, but may be formed to keep the etching process conditions constant at all locations and prevent a loading effect. Also, the dummy gate stack pattern GPc may be formed to prevent a dishing phenomenon in a subsequent CMP (Chemical Mechanical Polishing) process for forming an interlayer insulating film.

In the NMOS region, the first gate insulating film 13a, the first high dielectric constant film 15a, the N-type work function pattern 17a, the first gate stack pattern GPa, and the first gate capping film 30a may be sequentially stacked. The first gate stack pattern GPa may include a first lower electrode 21a, a first central electrode 23a, and a first upper electrode 25a.

In the PMOS region, the second gate insulating film 13b, the second high dielectric constant film 15b, the P-type work function pattern 17b, the second gate stack pattern GPb, and the second gate capping film 30b may be stacked sequentially. The second gate stack pattern GPb may include a second lower electrode 21b, a second central electrode 23b, and a second upper electrode 25b.

At the boundary between the NMOS region and the PMOS region, the dummy gate insulating film 13c, the dummy high dielectric constant film 15c, the dummy work function pattern 17c, the dummy gate stack pattern GPc, and the dummy gate capping film 30c may be stacked sequentially. The dummy gate stack pattern GPc may include a dummy lower electrode 21c, a dummy central electrode 23c, and a dummy upper electrode 25c.

The dummy gate stack pattern GPc may include a first portion C1 adjacent to the NMOS region, and a second portion C2 adjacent to the PMOS region.

In the second portion C2 of the dummy gate stack pattern GPc, a dummy high dielectric constant film 15c may not be disposed under the dummy gate stack pattern GPc. However, embodiments of the technical idea of the present disclosure are not limited thereto.

The first gate insulating film 13a and the second gate insulating film 13b may be formed of and/or include, for example, silicon oxide, silicon oxynitride or a combination thereof. The first high dielectric constant film 15a, the second high dielectric constant film 15b, and the dummy high dielectric constant film 15c may be formed of and/or include the same material as the high dielectric constant film 15 explained in FIGS. 1 to 5.

The N-type work function pattern 17a and the dummy work function pattern 17c may be formed of and/or include, for example, lanthanum (La), lanthanum oxide (LaO), magnesium (Mg), magnesium oxide (MgO), tantalum (Ta), tantalum nitride (TaN), and niobium (Nb). The P-type work function pattern 17b may be formed of and/or include aluminum (Al), aluminum oxide film (AlO), titanium nitride (TiN), tungsten nitride (WN), and/or ruthenium oxide (RuO).

The first lower electrode 21a, the second lower electrode 21b, and the dummy lower electrode 21c may each include the same material as the lower electrode (21 of FIG. 2). The first central electrode 23a, the second central electrode 23b, and the dummy central electrode 23c may each include the same material as the central electrode (23 of FIG. 2). The first upper electrode 25a, the second upper electrode 25b, and the dummy upper electrode 25c may each include the same material as the upper electrode (25 of FIG. 2).

The first gate capping film 30a, the second gate capping film 30b, and the dummy gate capping film 30c may each include the same material as the gate capping film (30 of FIG. 2).

In some embodiments, in the second isolation film 9b, the upper part of the fourth liner 5b may protrude beyond the upper parts of the third liner 3b and the second buried insulating film 7b. A first recess R1 may be formed at the upper part of the third liner 3b. A second recess R2 may be formed at the upper part of the second buried insulating film 7b. The depth of the second recess R2 may be greater than the depth of the first recess R1. For example, the second buried insulating film 7b may be recessed further than the third liner 3b.

In the dummy element isolation film 9c, the upper part of the sixth liner 5c may protrude beyond the upper parts of the fifth liner 3c and the third buried insulating film 7c. A third recess R3 may be formed at the upper part of the fifth liner 3c adjacent to the second portion C2 of the dummy gate stack pattern GPc. A fourth recess R4 may be formed at the upper part of the third buried insulating film 7c adjacent to the second portion C2 of the dummy gate stack pattern GPc. A vertical depth to the lowest point of the third recess R3 may be equal to the vertical depth to the lowest point of the first recess R1. The vertical depth to the lowest point of the fourth recess R4 may be equal to the vertical depth to the lowest point of the second recess R2.

In the first element isolation film 9a, the upper part of the second liner 5a may protrude beyond the upper parts of the first liner 3a and the first buried insulating film 7a. A fifth recess R5 may be formed at the upper part of the first liner 3a. A sixth recess R6 may be formed at the upper part of the first buried insulating film 7a. The vertical depth to the lowest point of the fifth recess R5 may be less than the vertical depth to the lowest point of the sixth recess R6.

The vertical depth of the first recess R1 may be greater than the vertical depth of the fifth recess R5. The vertical depth of the second recess R2 may be greater than the vertical depth of the sixth recess R6.

A seventh recess R7 may be formed at the upper part of the fifth liner 3c adjacent to the first portion C1 of the dummy gate stack pattern GPc. An eighth recess R8 may be formed at the upper part of the third buried insulating film 7c adjacent to the first portion C1 of the dummy gate stack pattern GPc. The vertical depth to the lowest point of the seventh recess R7 may be equal to the vertical depth to the lowest point of the fifth recess R5. The vertical depth to the lowest point of the eighth recess R8 may be equal to the vertical depth to the lowest point of the sixth recess R6.

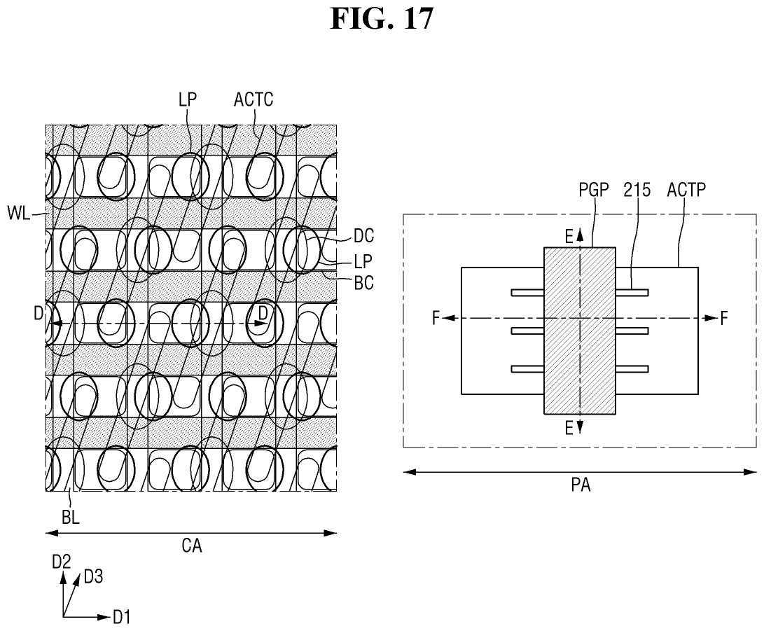

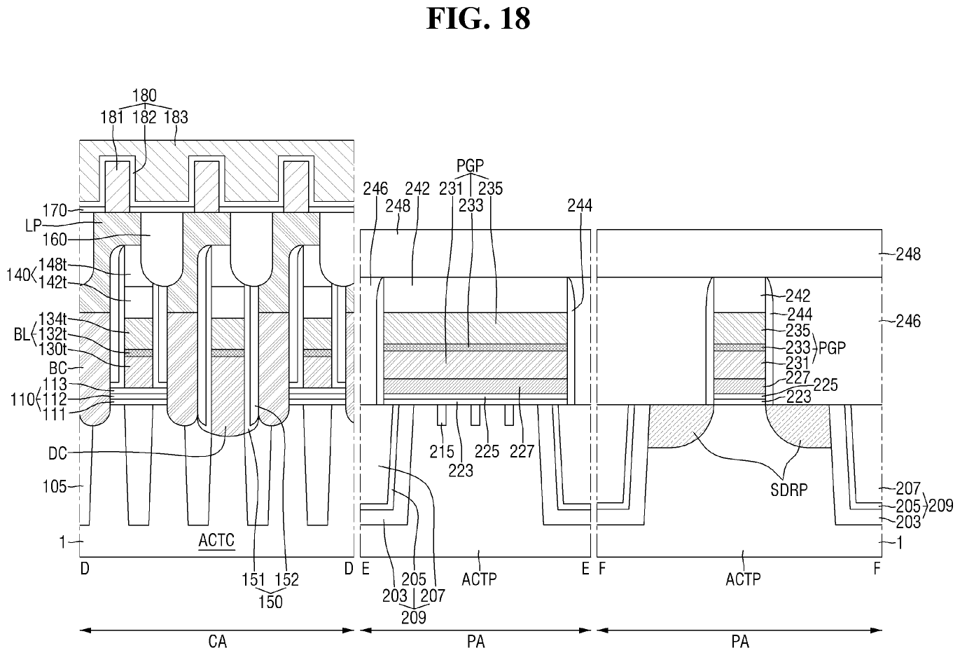

Hereinafter, a semiconductor memory device according to some other embodiments will be explained with reference to FIGS. 17 and 18.

FIG. 17 is an exemplary plan view of a semiconductor memory device according to some embodiments. FIG. 18 is a cross-sectional view taken along lines D-D, E-E and F-F of FIG. 17. For reference, the cross-sectional view taken along E-E line of FIG. 17 may be similar to FIG. 2, and the cross-sectional view taken along F-F line of FIG. 17 may be similar to FIG. 3. For convenience of explanation, previous descriptions of components explained using FIGS. 1 to 5 may be omitted.

Referring to FIGS. 17 and 18, a substrate 1 including a cell array region CA and a peripheral region PA is provided.

The peripheral region PA may be disposed around the cell array region CA. A plurality of transistors for driving the memory cells disposed in the cell array region CA may be disposed in the peripheral region PA. The memory cells disposed in the cell array region CA may include word lines WL, bit lines BL, and a capacitor 180, respectively. The transistor may be a NMOS transistor and/or a PMOS transistor.

A cell element isolation film 105 may be disposed in the substrate 1 of the cell array region CA. The cell element isolation film 105 may define a cell active region ACTC. As the design rules of the semiconductor memory device decrease, the cell active region ACTC may be disposed in the form of a bar of a diagonal line or an oblique line, as shown. For example, the cell active region ACTC may extend in a third direction D3. The third direction D3 may be in a plane parallel to an upper surface of the substrate (e.g., a horizontal plane).

The cell active regions ACTC may be arranged to be parallel to each other in the first direction D1. An end portion of one cell active region ACTC may be arranged to be adjacent to the center of another adjacent cell active region ACTC. Here, the first direction D1 and the second direction D2 may be perpendicular to each other. The third direction D3 may be any direction between the first direction D1 and the second direction D2.

The substrate 1 may be a silicon polycrystalline substrate or an SOI substrate. The cell element isolation film 105 may be formed of and/or include an oxide liner, a nitride liner, and a buried insulating film, as explained with reference to FIG. 1.

A semiconductor memory device according to some embodiments may include various contact arrangements formed on the cell active region ACTC. Various contact arrangements may include, for example, a direct contact DC, a buried contact BC, a landing pad LP, and the like.

Here, the direct contact DC may be a contact that electrically connects the cell active region ACTC to the bit line BL. The buried contact BC may be a contact that connects the cell active region ACTC to a capacitor lower electrode 181. A contact area between the buried contact BC and the cell active region ACTC may be small. Therefore, a conductive landing pad LP may be introduced to enlarge the contact area with the cell active region ACTC and enlarge the contact area with the capacitor lower electrode 181.

The landing pad LP may be disposed between the cell active region ACTC and the buried contact BC, or may be disposed between the buried contact BC and the capacitor lower electrode 181. In the semiconductor memory device according to some embodiments, the landing pad LP may be disposed between the buried contact BC and the capacitor lower electrode 181. By enlarging the contact area through the introduction of the landing pad LP, the contact resistance between the cell active region ACTC and the capacitor lower electrode may decrease.

The word lines WL may be buried inside the substrate 1. The word lines WL may intersect the cell active region ACTC. The word lines WL may extend in the first direction D1. The word lines WL may be spaced apart from each other in the second direction D2. The word lines WL may be buried inside the substrate 1 and extend in the first direction D1. Although not shown, a doping region may be formed inside the cell active regions ACTC between the word lines WL. N-type impurities may be doped in the doping region.

A buffer film 110 may be disposed on the substrate 1 of the cell array region CA. The buffer film 110 may include a first cell insulating film 111, a second cell insulating film 112, and a third cell insulating film 113, which are sequentially stacked. The second cell insulating film 112 may include a material having an etching selectivity with the first cell insulating film 111 and the third cell insulating film 113. For example, the second cell insulating film 112 may be formed of and/or include silicon nitride. The first and third cell insulating films 111 and 113 may be formed of and/or include silicon oxide.

The bit lines BL may be disposed on the buffer film 110. The bit lines BL may intersect the substrate 1 and the word line WL. As shown in FIG. 17, the bit lines BL may extend in the second direction D2. The bit lines BL may be spaced apart from each other in the first direction D1.

The bit lines BL may include a bit line lower electrode 130t, a bit line central electrode 132t, and a bit line upper electrode 134t, which are sequentially stacked. The bit line lower electrode 130t may be formed of and/or include impurity-doped polysilicon. The bit line central electrode 132t may be formed of and/or include TiSiN. The bit line upper electrode 134t may be formed of and/or include tungsten (W). However, embodiments of the technical idea of the present disclosure are not limited thereto.

A bit line capping pattern 140 may be disposed on the bit line BL. The bit line capping pattern 140 may include a first bit line capping pattern 142t and a second bit line capping pattern 148t that are sequentially stacked. The first bit line capping pattern 142t and the second bit line capping pattern 148t may each be formed of and/or include silicon nitride.

A bit line spacer 150 may be disposed on side walls of the bit line BL and side walls of the bit line capping pattern 140. The bit line spacer 150 may be disposed on the substrate 1 and the cell element isolation film 105 in the bit line BL portion in which the direct contact DC is formed. However, in some embodiments the bit line spacer 150 may be disposed on the buffer film 110 in the portion in which the direct contact DC is not formed.

Although the bit line spacer 150 may be a single layer in some embodiments, as shown in FIG. 18, in some embodiments the bit line spacer 150 may be a multi-layer bit line spacer 150 including first and second bit line spacers 151 and 152. For example, the first and second bit line spacers 151 and 152 may be formed of and/or include, but are not limited to, one of silicon oxide film, silicon nitride film, silicon oxynitride film (SiON), silicon oxycarbonitride film (SiOCN), air, and combinations thereof.

The buffer film 110 may be interposed between the bit line BL and the cell element isolation film 105, and between the bit line spacer 150 and the substrate 1.

The bit line BL may be electrically connected to the doping region of the cell active region ACTC by the direct contact DC. The direct contact DC may be formed of, for example, impurity-doped polysilicon.

The buried contact BC may be disposed between a pair of adjacent bit lines BL. The buried contacts BC may be spaced apart from each other. The buried contacts BC may be formed of and/or include at least one of impurity-doped polysilicon, conductive silicide compound, conductive metal nitride and metal. The buried contacts BC may have island shapes that are spaced apart from each other in a plan view. The buried contact BC may penetrate the buffer film 110 and abut on the doping region of the cell active region ACTC.

A landing pad LP may be formed on the buried contact BC. The landing pad LP may be electrically connected to the buried contact BC. The landing pad LP may partially overlap the upper face of the bit line BL. The landing pad LP may be formed of and/or include, for example, at least one of impurity-doped semiconductor material, conductive silicide compounds, conductive metal nitrides, conductive metal carbides, metals, and metal alloys.

A pad isolation insulating film 160 may be formed on the landing pad LP and the bit line BL. For example, the pad isolation insulating film 160 may be disposed on the bit line capping pattern 140. The pad isolation insulating film 160 may define a region of the landing pad LP that forms a plurality of isolation regions. Also, the pad isolation insulating film 160 may not cover the upper face of the landing pad LP.

The pad isolation insulating film 160 may include an insulating material, and electrically isolate the plurality of landing pads LP from each other. For example, the pad isolation insulating film 160 may be formed of and/or include at least one of a silicon oxide film, a silicon nitride film, a silicon oxynitride film, a silicon oxycarbonitride film, and a silicon carbonitride film.

An etching stop film 170 may be disposed on the pad isolation insulating film 160 and the landing pad LP. The etching stop film 170 may be formed of and/or include at least one of silicon nitride film, silicon carbonitride film, silicon boron nitride film (SiBN), silicon oxynitride film, and silicon oxycarbide film.

A capacitor 180 may be disposed on the landing pad LP. The capacitor 180 may be electrically connected to the landing pad LP. A part of the capacitor 180 may be disposed inside the etching stop film 170. The capacitor 180 includes a capacitor lower electrode 181, a capacitor dielectric film 182, and a capacitor upper electrode 183.

The capacitor lower electrode 181 may be disposed on the landing pad LP. The capacitor lower electrode 181 is shown to have a pillar shape, but embodiments are not limited thereto. The capacitor lower electrode 181 may have a cylindrical shape. The capacitor dielectric film 182 is formed on the capacitor lower electrode 181. The capacitor dielectric film 182 may be formed along the profile of the capacitor lower electrode 181. The capacitor upper electrode 183 is formed on the capacitor dielectric film 182. The capacitor upper electrode 183 may wrap the outer side walls of the capacitor lower electrode 181.

As an example, the capacitor dielectric film 182 may be disposed in a portion that vertically overlaps the capacitor upper electrode 183. As another example, unlike the shown example, the capacitor dielectric film 182 may include a first portion that vertically overlaps the capacitor upper electrode 183, and a second portion that does not vertically overlap the capacitor upper electrode 183. That is, the second portion of the capacitor dielectric film 182 is a portion that is not covered with the capacitor upper electrode 183.

The capacitor lower electrode 181 and the capacitor upper electrode 183 may each be formed of and/or include, for example, a doped semiconductor material, conductive metal nitride (e.g., titanium nitride, tantalum nitride, niobium nitride or tungsten nitride, etc.), a metal (e.g., ruthenium, iridium, titanium, tantalum, etc.), and conductive metal oxide (e.g., iridium oxide or niobium oxide, etc.).

The capacitor dielectric film 182 may be formed of and/or include, for example, but is not limited to, at least one of silicon oxide, silicon nitride, silicon oxynitride, high dielectric constant materials, and combinations thereof. In the semiconductor memory device according to some embodiments, the capacitor dielectric film 182 may be formed of and/or include a stacked film structure in which zirconium oxide, aluminum oxide, and zirconium oxide are sequentially stacked. In the semiconductor memory device according to some embodiments, the capacitor dielectric film 182 may include a dielectric film formed of and/or including hafnium (Hf). In the semiconductor memory device according to some embodiments, the capacitor dielectric film 182 may have a stacked film structure formed of and/or including a ferroelectric material film and a paraelectric material film.

A peripheral active region ACTP may be defined by the peripheral element isolation film 209 in the peripheral region PA. The peripheral element isolation film 209 may include a first peripheral liner film 203, a second peripheral liner film 205, and a peripheral buried insulating film 207. The first peripheral liner film 203 may be conformally disposed along the inner side walls and the bottom face of the trench formed in the substrate 1 of the peripheral region PA. The second peripheral liner film 205 may be disposed on the first peripheral liner film 203. The peripheral buried insulating film 207 may be disposed on the second peripheral liner film 205. The second peripheral liner film 205 may be interposed between the first peripheral liner film 203 and the peripheral buried insulating film 207.

The first peripheral liner film 203 may be formed of the same material as the first liner film (3 of FIG. 2). The second peripheral liner film 205 may be formed of the same material as the second liner film (5 of FIG. 2). The peripheral buried insulating film 207 may be formed of the same material as the buried insulating film (7 of FIG. 2).

A recess may be disposed in the substrate 1 of the peripheral region PA. The recess may be substantially the same as the recess RC explained using FIGS. 1 to 5. A peripheral sub-element isolation film 215 may be disposed inside the recess. Explanation of the peripheral sub-element isolation film 215 may be substantially the same as that of the sub-element isolation film 10 explained in FIGS. 1 to 5.

That is, a height of the peripheral sub-element isolation film 215 may be less than a height of the peripheral element isolation film 209. The upper face of the peripheral sub-element isolation film 215 may be disposed in the same plane as the upper face of the peripheral element isolation film 209. The height from the lower face of the substrate 1 of the peripheral region PA to the bottom face of the peripheral sub-element isolation film 215 is greater than the height from the lower face of the substrate 1 of the peripheral region PA to the bottom face of the peripheral element isolation film 209. The height from the upper face of the substrate 1 of the peripheral region PA to the bottom face of the peripheral element isolation film 209 may be greater than the height from the upper face of the substrate 1 of the peripheral region PA to the bottom face of the peripheral sub-element isolation film 215.

A peripheral gate structure may be disposed on the substrate of the peripheral region PA. The peripheral gate structure may include a peripheral gate insulating film 223, a peripheral high dielectric constant film 225, a peripheral work function pattern 227, a peripheral gate stack pattern PGP, a peripheral gate capping film 242, and a peripheral gate spacer 244.

The peripheral gate insulating film 223 may extend along the upper face of the peripheral active region ACTP, the upper face of the peripheral element isolation film 209, and the upper face of the peripheral sub-element isolation film 215. The peripheral gate insulating film 223 may include a first portion extending along the upper face of the peripheral active region ACTP, a second portion extending along the upper face of the peripheral element isolation film 209, and a third portion extending along the upper face of the peripheral sub-element isolation film 215. The thickness of the first portion, the thickness of the second portion, and the thickness of the third portion may be the same as each other. The peripheral gate insulating film 223 may be formed of and/or include, for example, silicon oxide.

The peripheral high dielectric constant film 225 may be disposed on the peripheral gate insulating film 223. The peripheral high dielectric constant film 225 may include the same material as the high dielectric constant film (15 of FIG. 2). The peripheral work function pattern 227 may be disposed on the peripheral high dielectric constant film 225. The peripheral work function pattern 227 may include the same material as the work function pattern (17 of FIG. 2).

The peripheral gate stack pattern PGP is disposed on the peripheral work function pattern 227. The peripheral gate stack pattern PGP may include a peripheral lower electrode 231, a peripheral central electrode 233, and a peripheral upper electrode 235. The peripheral lower electrode 231, the peripheral central electrode 233, and the peripheral upper electrode 235 may each include the same material as those of the lower electrode (21 of FIG. 2), the central electrode (23 of FIG. 2), and the upper electrode (25 of FIG. 2).

In some embodiments, the stack structure of the bit line BL and the stack structure of the peripheral gate stack pattern PGP may be the same. For example, the bit line lower electrode 130t and the peripheral lower electrode 231 may be formed through the same process. The bit line central electrode 132t and the peripheral central electrode 233 may be formed through the same process. The bit line upper electrode 134t and the peripheral upper electrode 235 may be formed through the same process. That is, the thickness of the bit line lower electrode 130t may be substantially the same as the thickness of the peripheral lower electrode 231. The thickness of the bit line central electrode 132t may be substantially the same as the thickness of the peripheral central electrode 233. The thickness of the bit line upper electrode 134t may be substantially the same as the thickness of the peripheral upper electrode 235. However, embodiments of the technical idea of the present disclosure are not limited thereto.

In some other embodiments, the stack structure of the bit line BL and the stack structure of the peripheral gate stack pattern PGP may be different from each other. The bit line BL and the gate stack pattern PGP may be formed through different processes. Accordingly, the thickness of the bit line lower electrode 130t may be different from the thickness of the peripheral lower electrode 231. The thickness of the bit line central electrode 132t may be different from the thickness of the peripheral central electrode 233. The thickness of the bit line upper electrode 134t may be different from the thickness of the peripheral upper electrode 235.

The peripheral gate capping film 242 may be disposed on the peripheral gate stack pattern PGP. The peripheral gate capping film 242 may include the same material as the gate capping film (30 of FIG. 2). In some embodiments, the peripheral gate capping film 242 may be formed through the same process as the first bit line capping pattern 142t. Accordingly, the thickness of the peripheral gate capping film 242 may be substantially the same as the thickness of the first bit line capping pattern 142t. However, embodiments of the technical idea of the present disclosure are not limited thereto. The peripheral gate capping film 242 may be formed through a process different from that of the first bit line capping pattern 142t.

The peripheral gate spacer 244 may be disposed on side walls of the peripheral gate stack pattern PGP, side walls of the peripheral gate capping film 242, side walls of the peripheral work function pattern 227, side walls of the peripheral high dielectric constant film 225, and side walls of the peripheral gate insulating film 223. The peripheral gate spacers 244 may include the same material as the gate spacer (40 of FIG. 2).

The side walls of the peripheral gate spacer 244 and the substrate 1 may be covered with the peripheral interlayer insulating film 246. The peripheral interlayer insulating film 246 may be formed of and/or include, for example, silicon oxide. A capping film 248 may be disposed on the peripheral interlayer insulating film 246. The capping film 248 may function as an etching stop film. The capping film 248 may be formed of a material different from that of the peripheral interlayer insulating film 246. For example, the capping film 248 may be formed of and/or include silicon nitride. The thickness of the capping film 248 may be substantially the same as the thickness of the second bit line capping pattern 148t.

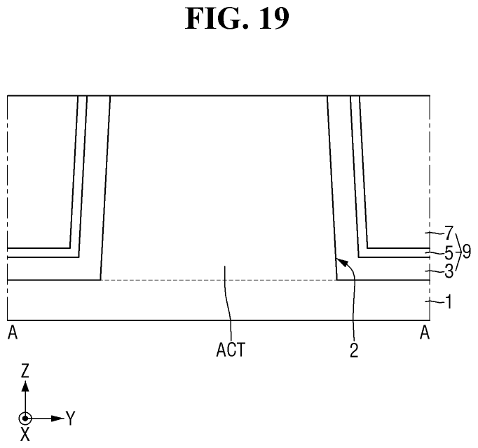

A method for fabricating a semiconductor memory device according to some embodiments will be described below with reference to FIGS. 19 to 25.

FIGS. 19 to 25 are cross-sectional views sequentially showing processes of fabricating the semiconductor memory device having the cross-section of FIG. 2.

First, referring to FIG. 19, the substrate 1 may be provided. The trench 2 may be formed in the substrate 1. The trench 2 may define an active region ACT (e.g., the side wall of the trench may define the active region ACT). The element isolation film 9 may be formed in the trench 2. The element isolation film may define the active region ACT. The first liner film 3 may be formed along the inner side wall and bottom face of the trench 2. The first liner film 3 may be formed conformally. The second liner film 5 may be formed on the first liner film 3. The second liner film 5 may be formed conformally. The buried insulating film 7 may be formed on the second liner film 5. The buried insulating film 7 may fill the remaining trench 2 after the first liner film 3 and the second liner film 5 are disposed.

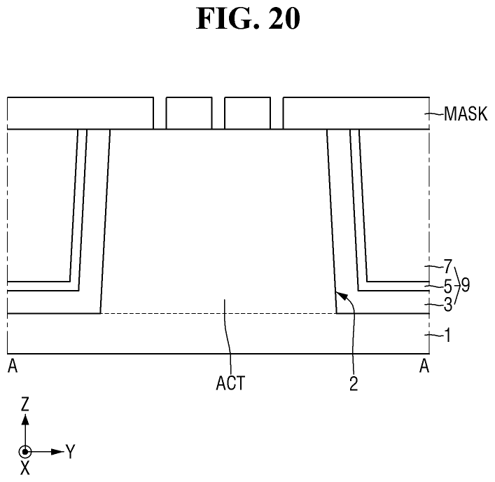

Referring to FIG. 20, a mask film MASK may be formed on the substrate 1. The mask film MASK may have an opening that roughly defines the position of the recess RC or the sub-element isolation film 10. The mask film MASK may be at least one of a photoresist film, ACL, SOH, and SOC.

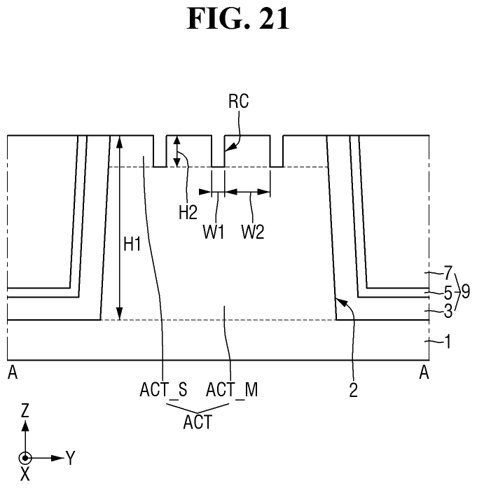

Referring to FIG. 21, a part of the substrate 1 may be etched, using the mask film MASK as an etching mask. A part of the substrate 1 may be etched to form the recess RC. The recess RC may define the plurality of sub-regions ACT_S. A region of the cell active region ACTC except the plurality of the sub-regions ACT_S may be a main active region ACT_M.

In some embodiments, the second height H2 of the recess RC in the z-direction Z is less than the first height H1 of the element isolation film 9 in the z-direction Z. That is, the height of the bottom face of the element isolation film 9 on the basis of the lower face of the substrate 1 is less than the height of the bottom face of the recess RC on the basis of the lower face of the substrate 1. After that, the mask film MASK may be removed.

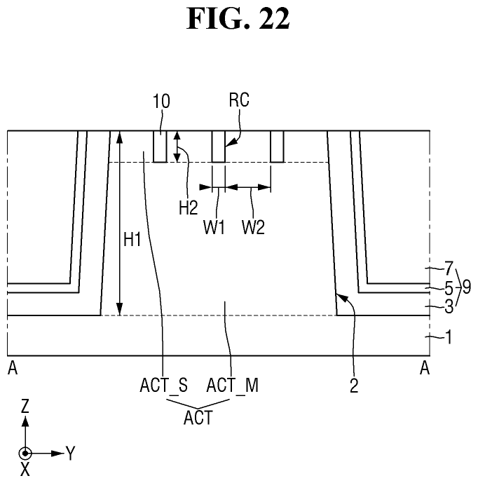

Referring to FIG. 22, the sub-element isolation film 10 may be formed inside the recess RC. The sub-element isolation film 10 may fill the recess RC. The upper face of the sub-element isolation film 10 may be disposed on the same plane as the upper face of the element isolation film 9.

The second height H2 of the sub-element isolation film 10 in the z-direction Z is less than the first height H1 of the element isolation film 9 in the z-direction Z. The height of the bottom face of the element isolation film 9 on the basis of the lower face of the substrate 1 is less than the height of the bottom face of the sub-element isolation film 10 on the basis of the lower face of the substrate 1.

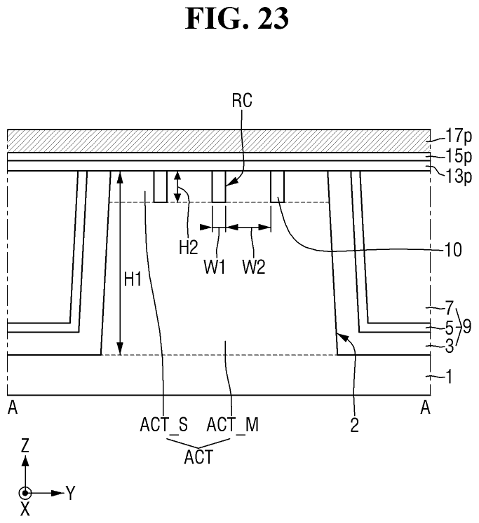

Referring to FIG. 23, a pre-gate insulating film 13p, a pre-high dielectric constant film 15p, and a pre-work function pattern 17p may be sequentially stacked on the substrate 1.

The pre-gate insulating film 13p may extend along the upper face of the element isolation film 9, the upper face of the active region ACT, and the upper face of the sub-element isolation film 10. The pre-gate insulating film 13p may be formed to have a constant thickness. The pre-gate insulating film 13p may be formed of and/or include, for example, silicon oxide, silicon oxynitride or a combination thereof.

The pre-high dielectric constant film 15p may be formed of and/or include a material having a dielectric constant greater than that of silicon oxide. For example, the pre-high dielectric constant film 15p may be formed of and/or include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The pre-work function pattern 17p may include an N-type metal or a P-type metal. For example, the pre-work function pattern 17p may be formed of and/or include at least one of lanthanum (La), lanthanum oxide (LaO), magnesium (Mg), magnesium oxide (MgO), tantalum (Ta), tantalum nitride (TaN), and niobium (Nb). Alternatively, the pre-work function pattern 17p may be formed of and/or include aluminum (Al), aluminum oxide film (AlO), titanium nitride (TiN), tungsten nitride (WN), and/or ruthenium oxide (RuO).

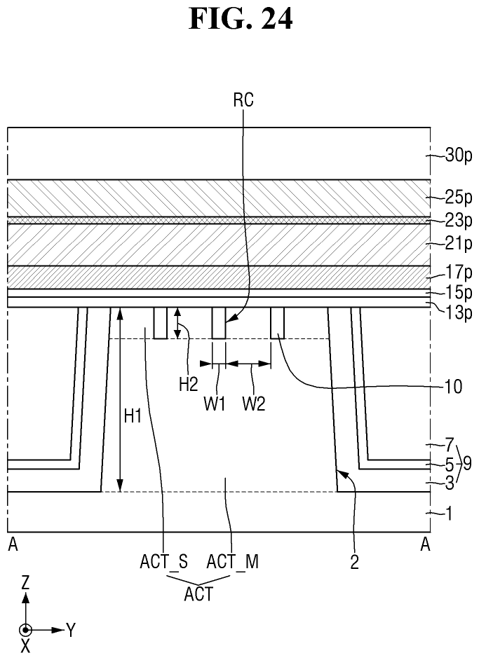

Referring to FIG. 24, a pre-lower electrode 21p, a pre-central electrode 23p, a pre-upper electrode 25p, and a pre-gate capping film 30p may be sequentially stacked on the pre-work function pattern 17p.

The pre-lower electrode 21p may include impurity-doped polysilicon. The pre-central electrode 23p may be formed of and/or include TiSiN. The pre-upper electrode 25p may be formed of and/or include tungsten (W). The pre-gate capping film 30p may be formed of and/or include silicon nitride. However, embodiments of the technical idea of the present disclosure are not limited thereto.

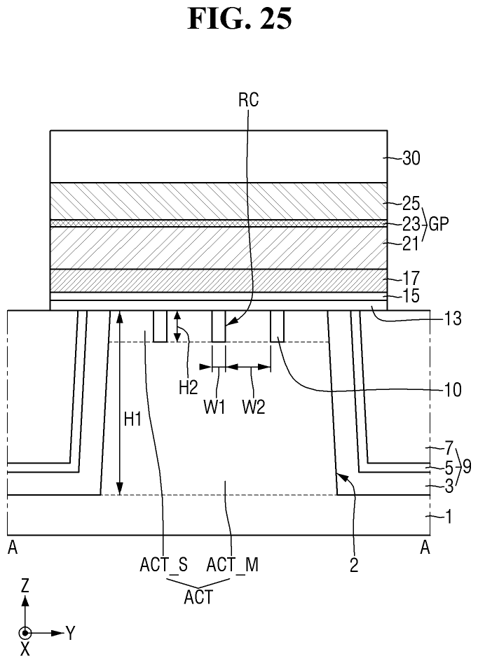

Referring to FIG. 25, the pre-gate insulating film 13p, the pre-high dielectric constant film 15p, the pre-work function pattern 17p, the pre-lower electrode 21p, the pre-central electrode 23p, the pre-upper electrode 25p, and the pre-gate capping film 30p may be patterned to form the gate insulating film 13, the high dielectric constant film 15, the work function pattern 17, the gate stack pattern GP, and the gate capping film 30.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor memory device comprising:
a substrate including an active region;
an element isolation film disposed in the substrate and that defines the active region;
a recess which is disposed in the active region and extends in a first direction; and
a gate structure extending in a second direction on the active region,
wherein the gate structure includes a gate insulating film, a gate stack pattern, and a gate capping pattern which are sequentially stacked,
wherein the gate insulating film extends along an upper face of the active region, and a part of the gate insulating film fills the recess, and
wherein a height from a lower face of the substrate to a bottom face of the element isolation film is less than a height from the lower face of the substrate to a bottom face of the recess.

2. The semiconductor memory device of claim 1, wherein a height of the element isolation film is greater than a height of the recess.

3. The semiconductor memory device of claim 1, wherein a width of an upper face of the recess in the second direction is less than a width of the upper face of the active region in the second direction.

4. The semiconductor memory device of claim 1, wherein a height from the bottom face of the element isolation film to a bottom face of the recess is greater than a height from the bottom face of the recess to an upper face of the recess.

5. The semiconductor memory device of claim 1, wherein a height from the bottom face of the element isolation film to a bottom face of the recess is less than a height from the bottom face of the recess to an upper face of the recess.

6. The semiconductor memory device of claim 1, wherein a height from the bottom face of the element isolation film to a bottom face of the recess is the same as a height from the bottom face of the recess to an upper face of the recess.

7. The semiconductor memory device of claim 1, wherein the gate insulating film includes a first portion which overlaps the upper face of the active region, and a second portion which overlaps an upper face of the element isolation film, and
wherein a thickness of the first portion is the same as a thickness of the second portion.

8. The semiconductor memory device of claim 1, wherein a width of the recess in the first direction is greater than a width of the gate structure in the first direction.

9. A semiconductor memory device comprising:
a substrate that includes an active region including a plurality of sub-regions;
an element isolation film which is disposed in the substrate and defines the active region; and
a plurality of sub-element isolation films which are disposed in the substrate, extend in a first direction, are spaced apart from each other in a second direction, and defines the plurality of sub-regions,
wherein a height of each of the plurality of sub-element isolation films in a third direction is less than a height of the element isolation film in the third direction, and
wherein widths of the plurality of sub-element isolation films in the second direction are less than widths of the plurality of sub-regions in the second direction.

10. The semiconductor memory device of claim 9, further comprising:
a gate structure which is disposed on the substrate and extends in the second direction,
wherein the gate structure includes a gate insulating film, a gate stack pattern, and a gate capping pattern which are sequentially stacked in the third direction,
wherein the gate insulating film includes a first portion that overlaps an upper face of the active region, and a second portion that overlaps an upper face of the element isolation film, and
wherein a thickness of the first portion in the third direction is the same as a thickness of the second portion in the third direction.

11. The semiconductor memory device of claim 10, wherein the gate insulating film further comprises a third portion that overlaps an upper face of the sub-element isolation film, and
wherein a thickness of the third portion in the third direction is the same as thicknesses of the first portion and the second portion in the third direction.

12. The semiconductor memory device of claim 9, wherein widths of each of the plurality of the sub-element isolation films in the second direction are less than widths of each of the plurality of the sub-regions in the second direction.

13. The semiconductor memory device of claim 9, wherein a height from a bottom face of the element isolation film to a bottom face of the sub-element isolation film in the third direction is greater than a height from the bottom face of the sub-element isolation film to an upper face of the sub-element isolation film.

14. The semiconductor memory device of claim 9, wherein a height from a bottom face of the element isolation film to a bottom face of the sub-element isolation film in the third direction is less than a height from the bottom face of the sub-element isolation film to an upper face of the sub-element isolation film.

15. The semiconductor memory device of claim 9, wherein a height from a bottom face of the element isolation film to a bottom face of the sub-element isolation film in the third direction is the same as a height from the bottom face of the sub-element isolation film to an upper face of the sub-element isolation film.

16. A semiconductor memory device comprising:
a substrate including a cell array region and a peripheral region;
a plurality of memory cells which are disposed in the cell array region, and each include a word line, a bit line, and a capacitor;
a peripheral element isolation film which is disposed in the peripheral region of the substrate and defines a peripheral active region;
at least one or more recesses disposed in the peripheral active region;
a peripheral sub-element isolation film disposed in the recess; and
a plurality of transistors which are disposed on the substrate of the peripheral region, and control operations of the plurality of memory cells,
wherein a height from an upper face of the substrate to a bottom face of the peripheral element isolation film is greater than a height from an upper face of the substrate to a bottom face of the peripheral sub-element isolation film.

17. The semiconductor memory device of claim 16, wherein each of the plurality of transistors comprise a gate structure which includes a gate insulating film, a gate stack pattern, and a gate capping pattern sequentially stacked,
wherein the gate insulating film includes a first portion extending along an upper face of the peripheral active region, and a second portion extending along an upper face of the peripheral element isolation film, and
wherein a thickness of the first portion is the same as a thickness of the second portion.

18. The semiconductor memory device of claim 17, wherein the gate insulating film includes a third portion extending along an upper face of the peripheral sub-element isolation film, and
wherein a thickness of the third portion is the same as a thicknesses of the first and second portions.

19. The semiconductor memory device of claim 16, wherein an upper face of the peripheral element isolation film and an upper face of the peripheral sub-element isolation film are placed on the same plane.

20. The semiconductor memory device of claim 16, wherein the word line is disposed inside the substrate of the cell array region, and
wherein the bit lines intersect the word line, on the substrate of the cell array region.
